(19) United States
(12) Patent Application Publication
(10) Pub. No.: US 2023/0395112 A1
(43) Pub. Date: Dec. 7, 2023

(54) ELECTRICAL WRITE/READ OF HIGH-INFORMATION-DENSITY MAGNETIC THIN FILM

(71) Applicant: Northwestern University, Evanston, IL (US)

(72) Inventors: Matthew A. Grayson, Evanston, IL (US); Pedram Khalili-Amiri, Evanston, IL (US); Chulin Wang, Evanston, IL (US); Claire Cecelia Onsager, Evanston, IL (US); Sevde Nur Arpaci, Wilmette, IL (US); Victor Lopez Dominguez, Evanston, IL (US)

(21) Appl. No.: 18/327,725

(22) Filed: Jun. 1, 2023

Related U.S. Application Data
(60) Provisional application No. 63/348,246, filed on Jun. 2, 2022.

(51) Int. Cl. G11C 11/15; G11C 11/16; G11B 5/31

(52) U.S. Cl. CPC G11C 11/15; G11B 5/3116; G11B 5/3169; G11C 11/161

(57) ABSTRACT

According to certain aspects of the present disclosure, a device is provided. The device includes a thin film of cobalt. A platinum layer is disposed on the thin film of cobalt. An aluminum layer is disposed on the platinum layer. The aluminum layer disposed on the platinum layer encapsulates the thin film of cobalt. A plurality of electrical contacts is in electrical communication with the thin film of cobalt. Two electrical contacts of the plurality of electrical contacts are configured to receive a write-current therebetween. Four electrical contacts of the plurality of contacts are configured for reading a 4-point resistance.

### CROSS-REFERENCE TO RELATED APPLICATIONS

The present application claims the benefit of priority under 35 U.S.C. § 119 from U.S. Provisional Patent Application Ser. No. 63/348,246 entitled “Electrical Write/Read of High-Information-Density Magnetic Thin Film,” filed on Jun. 2, 2022, the disclosure of which is hereby incorporated by reference in its entirety for all purposes.

### STATEMENT OF FEDERALLY FUNDED RESEARCH OR SPONSORSHIP

This invention was made with government support under grant numbers DMR-1720139 and ECCS-1912694 awarded by the National Science Foundation. The government has certain rights in the invention.

### TECHNICAL FIELD

The present disclosure generally relates to magnetic data storage, and more specifically relates to electrical read/write of high-information-density memristive film.

### BACKGROUND

Magnetic materials are traditionally used for data storage applications such as, for example, hard disks, and for data retrieval applications such as, for example, magnetic read heads. In certain standard ferromagnetic data storage such as, for example, magnetoresistive random-access memory (MRAM), one bit of information is stored per device that can read/write via an electrical current. In certain state of the art memory computing, information density is increased to one analog number per device. Higher information density, however, is still desired.

The description provided in the background section should not be assumed to be prior art merely because it is mentioned in or associated with the background section. The background section may include information that describes one or more aspects of the subject technology.

### SUMMARY

According to certain aspects of the present disclosure, a device is provided. The device includes a thin film of cobalt. A platinum layer is disposed on the thin film of cobalt. An aluminum layer is disposed on the platinum layer. The aluminum layer disposed on the platinum layer encapsulates the thin film of cobalt. A plurality of electrical contacts is in electrical communication with the thin film of cobalt. Two electrical contacts of the plurality of electrical contacts are configured to receive a write-current therebetween. Four electrical contacts of the plurality of contacts are configured for reading a 4-point resistance.

According to other aspects of the present disclosure, a method for fabricating a ferromagnetic thin film device is provided. The method includes transferring a thin film of cobalt out of a vacuum environment. The method includes depositing a platinum layer to the thin film of cobalt. The method includes depositing an aluminum layer to encapsulate the platinum layer deposited on the thin film of cobalt and the thin film of cobalt. The method includes patterning the thin film of cobalt, the platinum layer, and the aluminum layer. The method includes depositing a plurality of electrical contacts to the aluminum layer.

According to yet other aspects of the present disclosure, a ferromagnetic thin film device is provided. The ferromagnetic thin film device includes a thin film of cobalt. A platinum layer is disposed on the thin film of cobalt. An aluminum layer is disposed on the platinum layer. The aluminum layer disposed on the platinum layer encapsulates the thin film of cobalt. A plurality of electrical contacts is in electrical communication with the thin film of cobalt. Two electrical contacts of the plurality of electrical contacts are configured to receive a write-current therebetween. Four electrical contacts of the plurality of contacts are configured for reading a 4-point resistance. Two electrical contracts of the four electrical contracts of the plurality of electrical contacts are configured to receive a read-current therebetween and another two electrical contracts of the four electrical contacts of the plurality of electrical contacts are configured for reading a resistivity thereacross.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### BRIEF DESCRIPTION OF DRAWINGS

The disclosure is better understood with reference to the following drawings and description. The elements in the figures are not necessarily to scale, emphasis instead being placed upon illustrating the principles of the disclosure. Moreover, in the figures, like-referenced numerals may designate to corresponding parts throughout the different views.

FIG. 1A illustrates an electrical write protocol for a ferromagnetic thin film device according to certain aspects of the present disclosure.

FIG. 1B illustrates an electrical read protocol for a ferromagnetic thin film device according to certain aspects of the present disclosure.

FIG. 2A is a chart illustrating mean of 4-point resistances R̅ plotted against a tomography measurement index, m.

FIG. 2 B is a chart illustrating difference of the resistances from the mean, R−R̅.

FIG. 2C is a visual representation illustrating a reconstruction of conductivity map or from the mean tomography measurements shown in FIG. 2A.

FIG. 2D is a visual representation illustrating a reconstruction of the differentials σ−σ̅ from the resistance differences shown in FIG. 2B.

FIG. 3 is a cross-sectional view taken along line 3-3 of FIG. 1A, according to certain aspects of the present disclosure.

FIG. 4 illustrates an example process for fabricating a film device according to certain aspects of the present disclosure.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

The detailed description set forth below is intended as a description of various implementations and is not intended to represent the only implementations in which the subject technology may be practiced. As those skilled in the art would realize, the described implementations may be modified in various different ways, all without departing from the scope of the present disclosure. Accordingly, the drawings and description are to be regarded as illustrative in nature and not restrictive.

In certain aspects, the disclosed technology provides an improved read/write device based on magnetic materials that can encode information on magnetic domains with electrical current pulses and read that encoded information via resistive measurements using the same set of electrical contacts for encoding. In certain aspects, the device includes a ferromagnetic thin film with a plurality of electrical contacts such that current pulses can be injected between specific pairs of electrical contacts of the plurality of electrical contacts to induce change in local resistivity, which can be read out by electrical impedance tomography (EIT). Such devices can be implemented as a multi-real-value analog computation device or memristive device that is easy to mass produce and can achieve high information density. In certain aspects, the device is configured with a specific tomography algorithm such that multiple real numbers can be programmed and read out electrically in the device (e.g., a single device). In certain aspects, the disclosed technology provides a method for storing multi-valued analog memory on a single device. The temporal-awareness of the memory on the device, for example, allows application such as, but not limited to, neuromorphic computing and in-memory computing as an artificial neural network that is hardware-accelerated, easy to optimize, and natively suitable for temporal problem sets. Such aspects can greatly reduce the complexity of neural network training and deployment.

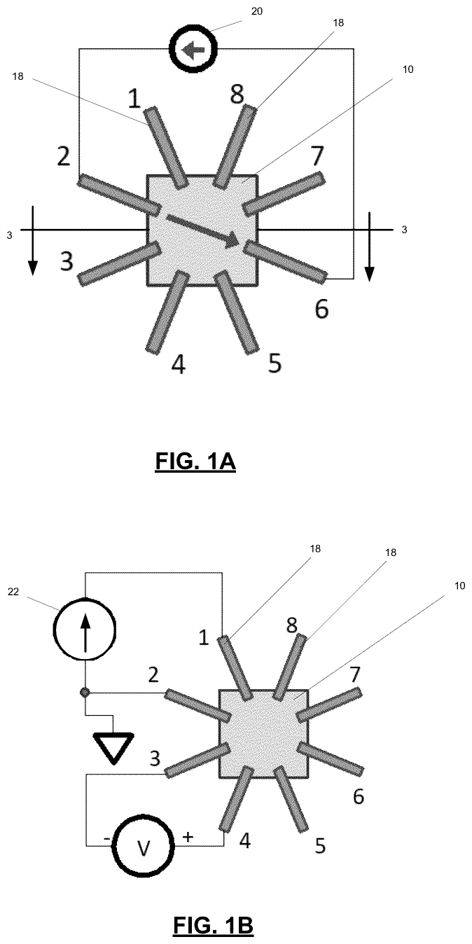

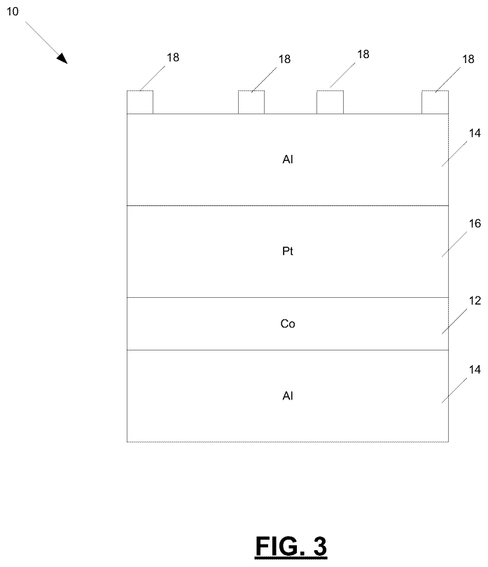

With reference to FIGS. 1A and 1B, a device 10 is illustrated according to certain aspects of the present disclosure. The device 10 can be a memristive film device including, but not limited to, magnetic memristive thin film devices such as a ferromagnetic thin film device. For example, as illustrated in FIG. 3, the device 10 can include a film of cobalt (Co) 12, which may be thin, encapsulated by an Aluminum (Al) layer 14 atop of a platinum (Pt) layer 16. The device 10 can be configured into a square although other configurations are also within the scope of the disclosure. In certain aspects, the device 10 is configured into a square with 25 microns in lateral dimension, for example, although other dimensions are within the scope of the present disclosure. In certain aspects, the thin film of Co 12 is 0.8 nm and is encapsulated by 2 nm of Al 14 atop of 2 nm of Pt 16. It should be understood that these dimensions are not limiting and that the thin film of Co 12, the Al layer 14, and the Pt layer 16 can be other appropriate dimensions.

The device 10 includes a plurality of electrical contacts 18 placed on a periphery of the device 10. In certain aspects, the material of the plurality of electrical contacts 18 can be, but is not limited to, gold (Au). In certain aspects, the plurality of electrical contacts 18 includes, but is not limited to, 8 contacts.

The device 10 is configured to receive an electrical current 20 to produce an electrical current write process. A large amplitude current write-pulse can change the magnetic domain structures of the device 10 along a current path, and thus creates changes in local resistivity of the device 10. Subsequent low-amplitude current read-pulses can measure the various 4-point resistances in the device 10, such that changes in local resistivity can be mapped. High-resolution electrical impedance tomography (EIT), for example, is an inverse solving method which can be used to read out resistivity of the device 10 as a function of position from the 4-point resistance series.

With particular reference to FIGS. 1A and 1B, a standard measurement protocol of the device 10 is described below. For example, a write-current 20 of 10 milliamps is sent between 2 contacts of the plurality of electrical contacts 18, such as between contact #2 and contact #6, as shown in FIG. 1A, which is then followed by a wait time for the signal to stabilize. Subsequently, a sequence of 4-point resistances is measured on the device with an order of 0.1 milliamp read-current 22, as illustrated in FIG. 1B. For a given number of contacts, C, of the plurality of contacts 18 there are C(C−3)/2 independent resistance measurements that can be used for tomography. Additional measurements can be incorporated to improve robustness of the tomography measurements. After all of the tomography measurements are measured, a write-pulse is sent from an orthogonal direction, and then followed by the same set of tomography measurements. Change in resistance of the device can be regarded as information stored in the device, which can be controllably programmed by selecting the contacts of the plurality of contacts, a current direction, a current magnitude, and a pulse width.

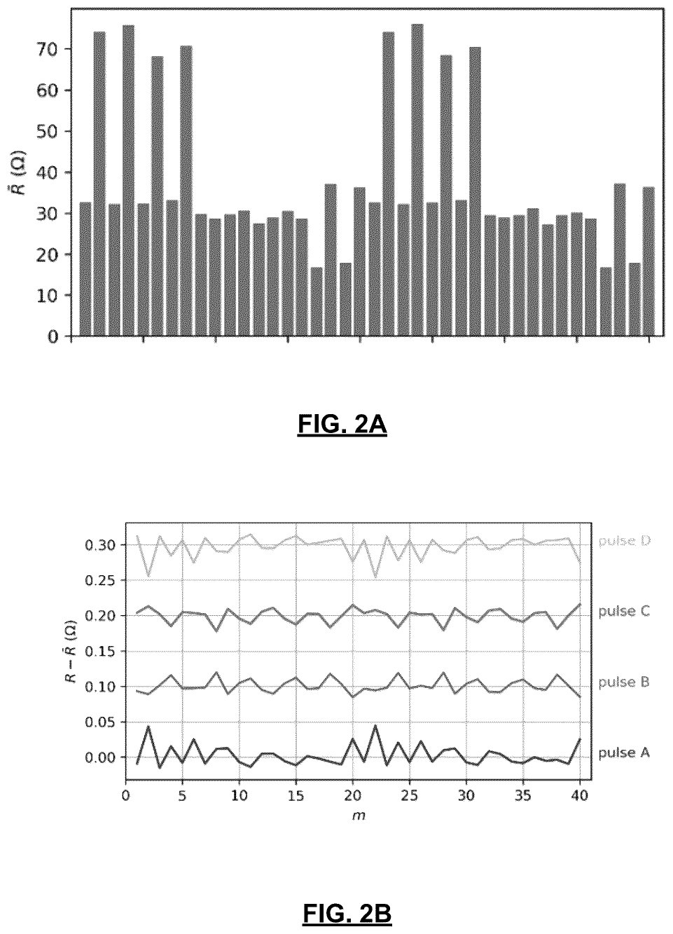

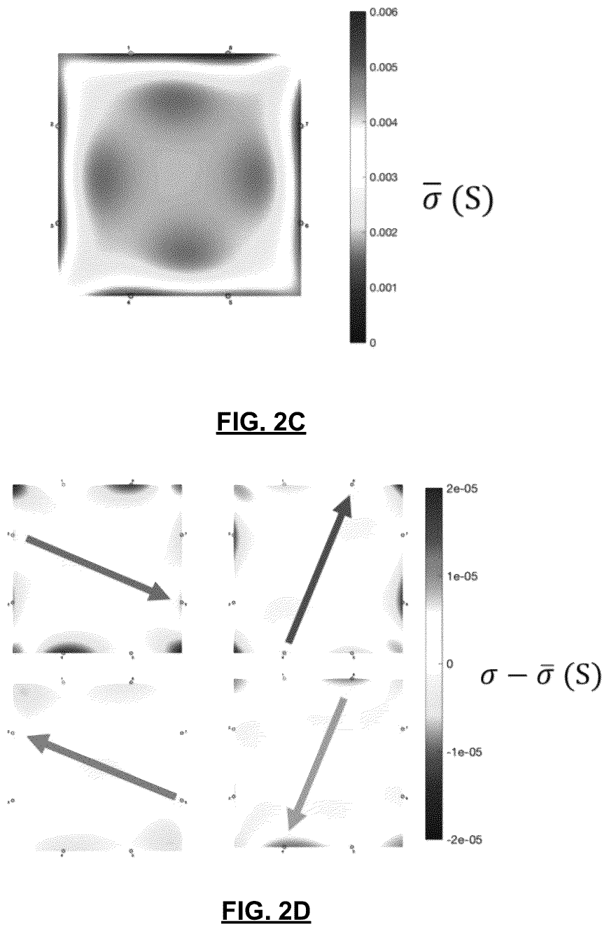

A local resistance map R(x, y) of the device is reconstructed using EIT. For example, within a series of 4 current pulses, I^{p}=10 mA, the average of the tomographic 4-point resistance measurements R̅ are shown in FIG. 2A, where the x-axis indicates the measurement index, m. After each current pulse, the difference from the mean, ΔR=R−R̅, is shown in FIG. 2B. As illustrated, the curves are artificially shifted by 0.1Ω spacing for clarity. The EIT maps the resistance measurements R, namely the data-space, to the conductivity map σ(x, y), namely the model-space. The mean resistances R̅ are reconstructed to a mean conductivity map σ̅(x, y), as shown in FIG. 2C, which shows good uniformity of the device. The differentials with respect to the mean, Δσ(x, y)=σ(x, y)−σ̅(x, y), are reconstructed from the resistance differences ΔR using singular value decomposition (SVD), shown in FIG. 2D, where each subpanel is a reconstruction of the conductivity of the device after a specific current pulse.

The differences evident in the four subpanels of FIG. 2D illustrate that the write process changes the local resistance map in different ways depending on the write-current history. The above describes an exemplary read/write memory process according to certain aspects of the subject technology.

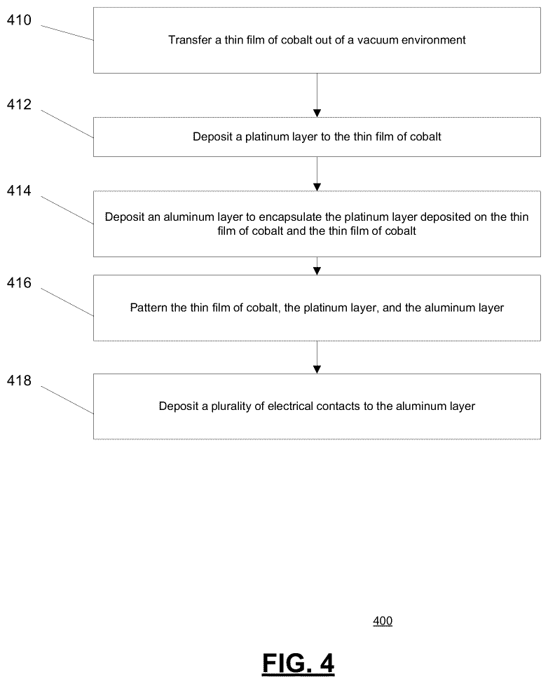

With reference to FIG. 4, an example fabrication process 400 of the device 10 is described below. For example, the device 10 can be fabricated using deposition and lithographic techniques. Several functional layers of the device 10 are deposited via sputter deposition and patterned into specific geometry using photolithography or electron beam lithography. In an exemplary process, a deposition rate of each layer is calibrated. The target layer thicknesses (e.g., thickness of the thin film of Co 12, the Al layer 14, and the Pt layer 16) are determined by the magnetic property of the material as well as the desired function of the device 10. The magnetic thin film (i.e., the thin film of Co 12) is then transferred out of a vacuum environment to be patterned via photolithography or electron beam lithography depending on the feature size of the device geometry. Next, the magnetic thin film (i.e., the thin film of Co 12) including the capping layer (i.e., the Al layer 14) and the adhesion layer (i.e., the Pt layer 16) is patterned into individual samples of desired shapes and sizes. Then, an additional photolithography process is used to define electrical contacts of the plurality of electrical contacts 18 to the device 10. Metal deposition and liftoff processes are used to deposit a high conductive metal such as, but not limited to, Au or Al. Each metal pad of the electrical contacts of the plurality of electrical contacts 18 connects a specific location of the magnetic thin film (i.e., the thin film of Co 12) to a large area on the substrate to facilitate, for example, electrical measurements of device operations.

FIG. 4 illustrates an example process 400 for fabricating a ferromagnetic thin film device. The process begins by proceeding to step 410 where the thin film of cobalt 12 is transferred out of a vacuum environment. As illustrated at step 412, a platinum layer 16 is deposited to the thin film of cobalt 12. An aluminum layer 14 is deposited to encapsulate the platinum layer 16 deposited on the thin film of cobalt 12 and the thin film of cobalt 12, as depicted at step 414. The thin film of cobalt 12, the platinum layer 16, and the aluminum layer 14 are patterned to form a shape, such as, but not limited to, a square, as depicted at step 416. As illustrated at step 418, a plurality of electrical contacts are deposited to the aluminum layer 14.

The word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” The term “some” refers to one or more. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. No claim element is to be construed under the provisions of 35 U.S.C. § 112, sixth paragraph, unless the element is expressly recited using the phrase “means for” or, in the case of a method claim, the element is recited using the phrase “step for”.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a sub combination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language claims and to encompass all legal equivalents. Notwithstanding, none of the claims are intended to embrace subject matter that fails to satisfy the requirements of the applicable patent law, nor should they be interpreted in such a way.

1. A device, comprising:
a thin film of cobalt;
a platinum layer disposed on the thin film of cobalt;
an aluminum layer disposed on the platinum layer, wherein the aluminum layer disposed on the platinum layer encapsulates the thin film of cobalt; and
a plurality of electrical contacts in electrical communication with the thin film of cobalt,
wherein two electrical contacts of the plurality of electrical contacts are configured to receive a write-current therebetween, and
wherein four electrical contacts of the plurality of electrical contacts are configured for reading a 4-point resistance.

2. The device of claim 1, wherein the thin film of cobalt is 0.8 nm, the aluminum layer is 2 nm, and the platinum layer is 2 nm.

3. The device of claim 2, wherein the thin film of cobalt is square shaped with a lateral dimension of 25 microns.

4. The device of claim 1, wherein the plurality of electrical contacts includes eight (8) electrical contacts.

5. The device of claim 4, wherein the plurality of electrical contacts is gold.

6. The device of claim 1, wherein the write-current is 10 milliamp.

7. The device of claim 6, wherein two electrical contracts of the four electrical contracts of the plurality of electrical contacts are configured to receive a read-current therebetween and another two electrical contracts of the four electrical contacts of the plurality of electrical contacts are configured for reading a resistivity thereacross.

8. The device of claim 7, wherein the read-current is 0.1 milliamp.

9. A method of fabricating a ferromagnetic thin film device, the method comprising:
transferring a thin film of cobalt out of a vacuum environment;
depositing a platinum layer to the thin film of cobalt;
depositing an aluminum layer to encapsulate the platinum layer deposited on the thin film of cobalt and the thin film of cobalt;
patterning the thin film of cobalt, the platinum layer, and the aluminum layer; and
depositing a plurality of electrical contacts to the aluminum layer.

10. The method of claim 9, wherein depositing the platinum layer to the thin film of cobalt and depositing the aluminum layer to encapsulate the platinum layer deposited on the thin film of cobalt are performed via sputter deposition.

11. The method of claim 9, wherein patterning the thin film of cobalt, the platinum layer, and the aluminum layer is performed by one of photolithography and electron beam lithography.

12. The method of claim 9, wherein depositing the plurality of electrical contacts to the aluminum layer is performed via metal deposition and liftoff.

13. The method of claim 12, wherein the plurality of electrical contacts are gold.

14. A device comprising:
a memristive film; and
a plurality of electrical contacts in electrical communication with the memristive film,
wherein two electrical contacts of the plurality of electrical contacts are configured to receive a write-current therebetween, and
wherein four electrical contacts of the plurality of electrical contacts are configured for reading a 4-point resistance.

15. The device of claim 14, wherein two electrical contracts of the four electrical contracts of the plurality of electrical contacts are configured to receive a read-current therebetween and another two electrical contracts of the four electrical contacts of the plurality of electrical contacts are configured for reading a resistivity thereacross.

16. The device of claim 15, wherein the memristive film comprises a film of cobalt being square shaped with a lateral dimension of 25 microns.

17. The device of claim 15, wherein the read-current is 0.1 milliamp.

18. The device of claim 14, wherein the plurality of electrical contacts includes eight (8) electrical contacts.

19. The device of claim 18, wherein the plurality of electrical contacts is gold.

20. The device of claim 14, wherein the write-current is 10 milliamp.
